(19) United States
(12) Patent Application Publication
(10) Pub. No.: US 2017/0349443 A1
(43) Pub. Date: Dec. 7, 2017

(54) REACTOR FOR THE DEPOSITION OF POLYCRYSTALLINE SILICON

(71) Applicant: Wacker Chemie AG, Munich (DE)

(72) Inventors: Tobias WEISS, Mehring (DE); Heinz KRAUS, Zeilarn (DE)

(73) Assignee: Wacker Chemie AG, Munich (DE)

(21) Appl. No.: 15/537,206

(22) PCT Filed: Dec. 18, 2015
(86) PCT No.: PCT/EP2015/080602

§ 371 Date: Jun. 16, 2017

(30) Foreign Application Priority Data
Jan. 7, 2015 (DE) 10 2015 200 070.2

(51) Int. Cl. C01B 33/035; C30B 29/06; B01J 4/00; B01J 19/02; C23C 16/24

(52) U.S. Cl. CPC C01B 33/035; B01J 19/02; C23C 16/24; B01J 4/002; C30B 29/06; B01J 2219/00132; B01J 2219/0236

(57) ABSTRACT

Reflective silver coatings on the inside surfaces of a Siemens reactor for polycrystalline silicon production are improved by a cold forming after-treatment of the silver coating.

### CROSS REFERENCE TO RELATED APPLICATIONS

This application is the U.S. National Phase of PCT Appln. No. PCT/EP2015/080602 filed Dec. 18, 2015, which claims priority to German Application DE 10 2015 200 070.2, filed Jan. 7, 2015, the disclosures of which are incorporated in their entirety by reference herein.

### BACKGROUND OF THE INVENTION

### Field of the Invention

The present invention relates to a reactor for deposition of polycrystalline silicon.

### Description of the Related Art

Polycrystalline silicon (polysilicon for short) serves as starting material in the production of monocrystalline silicon by crucible pulling (Czochralski or CZ method) or by zone melting (float zone or FZ method). This monocrystalline silicon is cut into wafers and, after a great many mechanical, chemical and mechanochemical processing operations, employed in the semiconductor industry for fabricating electronic components (chips).

However, in particular, polycrystalline silicon is needed to a greater extent for producing mono- or multicrystalline silicon by pulling or casting methods, this mono- or multicrystalline silicon being used for fabricating solar cells for photovoltaic applications.

The polycrystalline silicon is typically produced by the Siemens process. This comprises heating slim filament rods of silicon (“slim rods”) in a bell-shaped reactor (“Siemens reactor”) by direct passage of current and introducing a reaction gas comprising a silicon-containing component and hydrogen. The silicon-containing component of the reaction gas is generally a monosilane or a halosilane having the general composition SiHₙX₄₋ₙ (n=0, 1, 2, 3; X=Cl, Br, I). This component is preferably a chlorosilane or a chlorosilane mixture, most preferably trichlorosilane. Predominantly, SiH₄ or SiHCl₃ (trichlorosilane, TCS) is employed in a mixture with hydrogen.

A typical Siemens reactor essentially consists of a metallic base plate, a coolable bell jar placed thereover and forming a gas-tight seal therewith, nozzles for supplying gas and openings for removing reaction gas, and also the holders for the filament rods and the necessary input and output leads for the electric current.

The deposition reaction in the reactor typically requires high temperatures in the region of above 1000° C. at the surface of the filament rods in the reactor. The heating of the filament rods is achieved by direct passage of current. The supply of electricity is effected via electrodes with which the filament rods are held.

A large part of the supplied electrical energy is radiated in the form of heat and absorbed and dissipated by the reaction gas and the cooled reactor inner wall.

To reduce power consumption, it has been proposed to subject the reactor inner wall to treatment (for example electropolishing) or to coating with a material having a high reflectance. Known materials for coating the inside of the reactor are silver or gold since these materials have the highest theoretical reflectance.

DD 156273 A1 discloses a reactor for producing polysilicon having the particular feature that the inside of the reactor is made of electrochemically polished stainless steel.

EP 0 090 321 A2 describes a process for producing polysilicon wherein the walls of the reactor employed are made of a corrosion-resistant alloy and polished on their inner surface to a mirror finish.

KR 10-1145014 B1 discloses a deposition reactor comprising a Ni—Mn-alloy-coated inner wall for reducing the specific energy consumption during polysilicon deposition. The coating has a thickness of 0.1-250 μm.

US 2013/115374 A1 discloses a deposition reactor, the inner surface of which is at least partially provided with a so-called heat control layer. Cited characteristics of the heat control layer are emissivity coefficients of less than 0.1 and hardnesses of the layer of at least 3.5 Moh. The layer has a thickness of not more than 100 μm. The materials tungsten, tantalum, nickel, platinum, chromium and molybdenum are regarded as particularly preferable.

With regard to their reflection characteristics, coatings comprising silver and gold have advantages over an electropolished surface. Moreover, the use of electropolished stainless steel carries the risk of contaminating the polysilicon with iron.

US 2011/159214 A1 describes a reactor for polysilicon deposition, the inside of which had been coated with a layer of gold at least 0.1 μm thick. This can reduce the specific energy consumption since the reflection characteristics of gold are very high.

WO 2013/053495 A1 discloses a reactor for deposition of silicon from the gas phase, which comprises a reactor vessel having an inner surface which at least partially delimits a process space; and

a coating on at least part of the inner surface of the reactor vessel which comprises the following:
a first layer which is applied onto the inner surface of the reactor vessel at least in an upper region and has a higher reflectance for heat radiation than the uncoated inner surface of the reaction vessel; and a second layer which is applied onto a lower region of the inner surface of the reactor vessel and has a higher reflectance for heat radiation than the uncoated inner surface of the reaction vessel;
wherein the second layer is substantially thicker than the first layer. The first layer may be applied by electroplating, for example. In addition to silver it is also possible to use gold as coating material. The different thicknesses allow cost savings to be made.

When raw material costs are taken into account silver is preferable to gold. Moreover, silver is markedly less problematic than gold in terms of contamination of the high-purity polysilicon. When gold is used there is a risk of the gold diffusing into the polysilicon and leading to quality issues in downstream processes, for example in the production of monocrystalline silicon wafers.

DD 64047 A discloses a deposition process for producing low-phosphorus polysilicon. This is to be accomplished, inter alia, through the use of low-phosphorus materials (stainless steel, silver etc.) for the reactor inner wall.

U.S. Pat. No. 4,173,944 A claims a deposition apparatus where the surface of the bell jar encompassing the reaction space is made of silver or silverplated steel.

DE 956 369 C discloses a process for producing molded articles made of steel and plated with silver or alloys having a high silver content, characterized in that the silver/silver alloy is applied to the substrate in a molten state in the presence of atomic hydrogen. After solidification, the silver layer is then smoothed by planing, milling or other mechanical procedures.

DE 1 033 378 B describes a similar process where the priming layer made of silver is reinforced with molten silver to achieve the desired thickness.

DE 10 2010 017 238 A1 shows how silver may be applied to a steel surface. A thermal process (for example welding) causes the silver to join with the steel at the contact surface and silver and steel are securely joined together. The silver layer may subsequently be subjected to grinding or polishing.

It has been found that malfunctions in the deposition process may lead to silicon rods falling against the reactor wall. When the reactor inner wall is coated with a material, and when the hardness thereof is potentially lower than that of silicon, toppling silicon rods damage the coating. The extent of damage increases with, in addition to other influencing factors, decreasing hardness of the coating. When the reactor wall is coated with silver, this may lead to damage to the silver layer on account of the high hardness of silicon, which in turn can lead to deterioration of the reflection characteristics of the coating. This is associated with increased power consumption during the deposition process and—in order to avoid this—costly and inconvenient repairs of the reactor.

A further problem is that damage to the reactor wall can also result in the polysilicon product being of poorer quality. This is because, in some cases, the carrier wall for the coating, typically steel or stainless steel, may also be damaged. Corrosion of the carrier wall can lead to undesired introduction of foreign atoms (for example iron) into the polysilicon.

A fundamental problem with the use of coating materials such as nickel, gold, silver or other materials which improve reflection properties is that during the production process, for example at high temperatures, oxygen may dissolve in the coating material to a greater degree since in the course of the production process of the coating material (for example silver, gold or nickel) the materials must be brought to melting point (for example 961.9° C. for silver, 1064° C. for gold, 1455° C. for nickel).

Thus, for example, silver exhibits a relatively high solubility for oxygen, which increases with increasing temperature. Silver coatings may therefore have a high oxygen content. This is a disadvantage, since during operation of the deposition reactor, the oxygen dissolved in the coating material may effect undesired side reactions. For example brown/black silver oxide, dark nickel oxide or other dark-colored metal oxides may be formed which can negatively affect both the reflection properties of the reactor inner wall and the quality of the polysilicon produced.

Furthermore, hydrogen which is employed during the deposition process as a carrier gas for chlorosilanes may diffuse through the coating layer and react with dissolved or trapped oxygen to form water. This may lead to corrosion of the metal carrier sheet (steel or stainless steel) or to bubble formation in the coating layer culminating in detachment of the coating from the metal carrier sheet.

Moreover, during the production process for the coated metal sheet small air pockets may be formed between the steel sheet and the coating which can likewise lead to undesired side reactions or damage to the coating during the deposition process.

All of the problems described are associated with high repair costs and reactor downtime.

### SUMMARY OF THE INVENTION

The object to be achieved by the invention arose from the problems described.

This and other objects are achieved by a reactor for the deposition of polycrystalline silicon, which comprises a metallic base plate, a coolable bell jar placed thereover and forming a gas-tight seal therewith, nozzles for supplying gas and openings for removing reaction gas, and also holders for filament rods and input and output leads for electric current, wherein the inner walls of the bell jar are coated with a metal or with a metal alloy, characterized in that the coating has been mechanically aftertreated by hot forming and/or cold forming in such a way that the coating has undergone plastic deformation during the mechanical treatment.

### BRIEF DESCRIPTION OF THE DRAWINGS

FIG. 1 shows a schematic representation of a reactor.

### DETAILED DESCRIPTION OF THE PREFERRED EMBODIMENTS

The invention provides for working the coating by mechanical forming such that the coating has either a smooth, even structure or an irregular, non-smooth structure comprising indentations, dents or other depressions.

The coating preferably has a minimum thickness of 0.5 mm.

The mechanical forming may be a hot forming procedure and/or a cold forming procedure, preferably a cold forming procedure. Hot forming comprises plastic working of the surface above the recrystallization temperature, for example forging or welding. Cold forming comprises plastic working of the surface below the recrystallization temperature, for example peening and hammering.

Materials preferred for employment as the coating material are those which improve the reflection properties of the reactor inner wall with reference to the carrier material. These are in particular metals and metal alloys having an emissivity coefficient of less than 0.3, preferably less than 0.15. Preference is given to stainless steel, nickel, nickel alloys such as Hastelloy or Inconel, silver or gold. The use of silver is particularly preferred.

The invention provides for targeted aftertreatment of the coating by mechanical forming.

In one embodiment the base plate also has such a coating on its reactor-side surface, i.e. on the surface facing into the reactor space.

In contrast to the typical processing steps in coating processes, which are known from the prior art and referred to at the outset, the forming of the coating seeks to mechanically expel the coating-dissolved oxygen and also oxygen inclusions by plastic deformation of the coating.

This reduces the susceptibility to detachment of the coating from the carrier wall. The mechanically aftertreated coating exhibits improved adhesion of the coating to the metal carrier sheet. The formation of undesired metal oxide compounds which could negatively affect the reflection properties of the inner wall is reduced.

The surface may have a smooth appearance, such as after cold rolling and warm rolling for example, or may exhibit dents, indentations or other depressions, referred to in general terms as indentations hereinbelow, such as after hammering for example, wherein the surface treatment of the coating does not have a negative effect on the reflection properties of the coating.

Possible indentations preferably have a diameter of 1-100 mm, more preferably 5-30 mm, and a depth of preferably 0.1-2 mm, more preferably 0.1-1 mm.

The indentations may be discrete. In one embodiment at least some of the indentations are contiguous.

The forming of the coating may be hot forming or cold forming, i.e. mechanical working of the coating with plastic deformation of the coating. Hot forming is performed above the recrystallization and cold forming is performed below the recrystallization temperature. Preference is given to cold forming since the solubility of the oxygen is lower here.

Cold forming results in a microstructure change toward smaller crystallites and a higher dislocation density. This leads to an increase in the hardness of the coating.

On account of the higher hardness the coated surface is hardly, or at least less severely, damaged by toppling silicon rods. Cold forming accordingly expels oxygen dissolved in the coating and/or trapped oxygen bubbles and increases the hardness of the coating.

The production of the coating or plating, in particular of the silver coating/silver plating is carried out, for example, according to the processes described in DE 956 369 C and DE 1 033 378 B.

Plating is to be understood as meaning the application and secure joining of a layer, which has a film thickness of not less than of 0.5 mm and is composed of a metal or a metal alloy, to a carrier metal. The coating material may be coated onto the carrier metal by explosion plating, build-up welding, roll application, cold gas dynamic spraying or other known processes. These processes are usually performed at high temperature and/or pressure.

Cold gas dynamic spraying comprises accelerating very small particles of the coating material onto the surface to be coated at very high speed using a gas stream. Impact gives rise to plastic deformation of the sprayed material and the near-surface layers of the metal carrier sheet. This builds up a firmly adherent layer.

However, all coated metal carrier sheets are in principle formable, irrespective of the coating technology and irrespective of the material of the metal carrier sheets or of the coating.

The cold forming of the coating may be affected by cold rolling, deep drawing, bending, peening, hammering, shot peening or other processes for cold forming which cause dislocations in the microstructure and improve the hardness of the coating.

In these cold forming operations a metal carrier sheet (steel or stainless steel with the coating or plating disposed thereupon) is worked using a suitable tool on the coating side. The cold forming operation may be performed either as a last processing step after putting together the coated metal carrier sheets to form the deposition reactor or else beforehand on individual coated metal carrier sheets in an intermediate fabrication step.

Peening, hammering and cold rolling have proven to be particularly suitable cold forming operations. Hammering is particularly preferred.

Hammering cold forms the surface in indented regions.

After cold forming or hot forming the coating is preferably 0.5 to 5 mm thick, more preferably 0.5 to 3.5 mm.

It is preferable when silver is chosen as the coating material.

It is possible to employ as the silver not only silver of the highest possible purity (so-called ‘fine silver’) but also silver comprising alloying constituents (for example comprising nickel or the like).

Fine silver (Ag 4N) comprises at least 99.99 wt % of silver.

Silver comprising small proportions of alloying constituents, in particular fine grain silver (AgNi 0.15 having a nickel proportion of 0.15 wt %), is particularly preferable since fine grain silver has a higher hardness than silver and fine silver.

It is preferable when the inner walls of the reactor bell jar are silverplated sheet steel, wherein the silver plating is hammered.

The base plate/the reactor-side surface of the base plate is preferably also made of silverplated steel or stainless steel. In this case all surfaces of the reactor interior, delimited by the base plate and the bell jar, are silverplated.

The invention further relates to a process for producing polycrystalline silicon in such a reactor, which comprises introducing a reaction gas comprising a silicon-containing component and hydrogen into a CVD reactor containing at least one filament rod supplied with current by means of electrodes and thus heated by direct passage of current to a temperature at which polycrystalline silicon is deposited upon the filament rod.

Preferably, pairs of filament rods are connected at one end via a bridge to form a support body having an inverse U-shape. At the other end the filament rods are each connected to a respective electrode disposed on the reactor base plate. The two electrodes have opposite polarities.

The inverse U-shaped support body—when composed of silicon—requires initial preheating to approximately at least 250° C. to become electrically conductive and to be able to be heated by direct passage of current.

Finally, reaction gas comprising a silicon-containing component is supplied. The silicon-containing component of the reaction gas is preferably monosilane or halosilane of general formula SiHₙX₄₋ₙ (n=0, 1, 2, 3, 4; X=Cl, Br, I). The silicon-containing component is particularly preferably a chlorosilane or a chlorosilane mixture. The use of trichlorosilane is very particularly preferred. Monosilane and trichlorosilane are preferably employed in a mixture with hydrogen.

High-purity polysilicon is deposited upon the heated filament rods and the horizontal bridges to increase the diameter thereof with time. The process is terminated once the desired diameter has been achieved.

The polycrystalline silicon rods obtained by deposition are preferably comminuted into chunks, optionally cleaned, and packed in subsequent processing steps.

The features cited in connection with the abovedescribed embodiments of the process according to the invention may be correspondingly applied to the product according to the invention. Conversely, the features cited in connection with the abovedescribed embodiments of the product according to the invention may be correspondingly applied to the process according to the invention. These and other features of the embodiments according to the invention are elucidated in the description of the figures and in the claims. The individual features may be realized either separately or in combination as embodiments of the invention. These features may further describe advantageous implementations eligible for protection in their own right.

### LIST OF REFERENCE NUMERALS EMPLOYED

1 base plate
2 bell jar
3 reactor wall

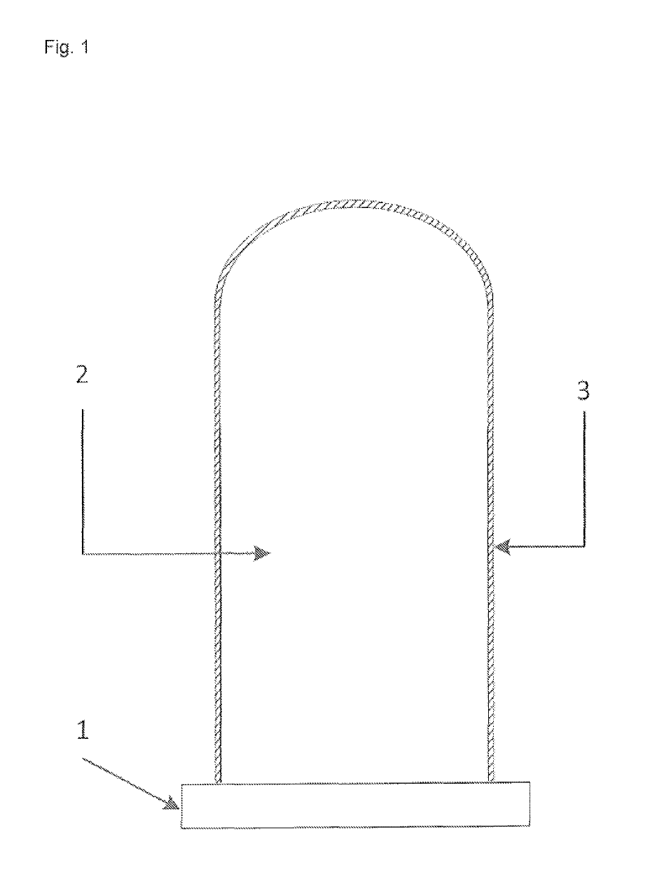

The reactor, as shown in FIG. 1 comprises a bell jar 2 disposed upon a base plate 1.

The reactor-interior-facing surface of the reactor wall 3 of the bell jar is silverplated and hammered.

In one embodiment the surface of the base plate 1 facing the reactor interior is also silverplated and hammered.

The description of illustrative embodiments hereinabove is to be understood as being exemplary. The disclosure made thereby enables a person skilled in the art to understand the present invention and the advantages associated therewith and also encompasses alterations and modifications to the described structures and processes obvious to a person skilled in the art. All such alterations and modifications and also equivalents shall therefore be covered by the scope of protection of the claims.

1.-8. (canceled)

9. A reactor for deposition of polycrystalline silicon, comprising:
a metallic base plate, a coolable bell jar placed thereover and forming a gas-tight seal therewith, nozzles for supplying gas and openings for removing reaction gas, and holders for filament rods and input and output leads for electric current, wherein the inner walls of the bell jar are coated with silver, and the silver coating has been mechanically after-treated by cold forming such that the coating has undergone plastic deformation during the mechanical after-treatment, wherein the cold forming takes place by peening, hammering or cold rolling.

10. The reactor of claim 9, wherein cold forming takes place by hammering.

11. The reactor of claim 9, wherein the bell jar inner walls and the base plate are coated with silver.

12. The reactor of claim 9, wherein the coating has a thickness of 0.5-5 mm.

13. The reactor of claim 12, wherein the coating is a coating comprising fine silver.

14. The reactor of claim 13, wherein the coating is a coating comprising fine grain silver.

15. The reactor of claim 9, wherein the coating comprises indentations after cold forming.

16. In a process for producing polycrystalline silicon, which comprises introducing a reaction gas comprising a silicon-containing component and hydrogen, by means of one or more nozzles, into a reactor which comprises at least one heated filament rod upon which silicon is deposited, the improvement comprising employing a reactor of claim 9.
